(19) United States
(12) Patent Application Publication
(10) Pub. No.: US 2014/0286733 A1
(43) Pub. Date: Sep. 25, 2014

(54) LOAD PORT AND EFEM

(71) Applicant: SINFONIA TECHNOLOGY CO., LTD., Tokyo (JP)

(72) Inventors: Gengoro Ogura, Tokyo (JP); Takaichi Hatano, Tokyo (JP)

(73) Assignee: SINFONIA TECHNOLOGY CO., LTD., Tokyo (JP)

(21) Appl. No.: 14/353,634

(22) PCT Filed: Nov. 8, 2012
(86) PCT No.: PCT/JP2012/078920

§ 371 Date: Apr. 23, 2014

(30) Foreign Application Priority Data
Nov. 9, 2011 (JP) 2011-245160

(51) Int. Cl. H01L 21/677

(52) U.S. Cl. CPC H01L 21/67775; H01L 21/67769
USPC 414/217.1

(57) ABSTRACT

There is provided a device capable of effectively increasing the number of wafers that is conveyed inside a wafer transport chamber and capable of improving the wafer conveyance processing capacity if an EFEM is used, without leading to a marked increase in installation area. A load port includes: a plurality of levels of loading tables are provided in the height direction; and wafers housed inside FOUP on top of each loading table is inserted into and removed from inside wafer transport chambers, in a state wherein each loading table is arranged at a wafer insertion/removal position on the front surface of the wafer transport chambers. The loading tables includes a transport mechanism that moves wafers forward and back in the front/rear direction, between a FOUP passing/receiving position at which the FOUP are handed over to a FOUP transport device and the wafer insertion/removal position.

### TECHNICAL FIELD

The present invention relates to a load port provided in front of a wafer transport chamber in a clean room, and to an Equipment Front End Module (EFEM) provided with the load port.

### BACKGROUND ART

In a semiconductor manufacturing process, wafers are processed in a clean room for improved yield and quality. Today, however, when the trends of high integration of devices and circuit miniaturization along with the adoption of larger wafers have progressed, it has become difficult to manage small dusts in an entire clean room in view of costs as well as from a technical point of view. Accordingly, instead of increasing the cleanliness of the entire interior of such a clean room, a system that incorporates “mini-environment system,” which locally increases the cleanliness only around wafers, has been adopted recently for transporting and otherwise processing wafers. The mini-environment system includes a storage container known as a Front-Opening Unified Pod (FOUP) for transporting and retaining a wafer in a highly clean environment. Such a FOUP constitutes an Equipment Front End Module (EFEM) in combination with a wafer transport chamber. In addition, a load port is used as important equipment, which functions as an interface for allowing a FOUP to insert/remove wafers into/from a wafer transport chamber and for passing/receiving a FOUP itself to/from a FOUP transport device.

In a state in which the FOUP is placed on the load port, the load port is provided with a door section, which is brought into close contact with a lid provided in a back surface of the FOUP. The door section and the lid are opened at the same time while in close contact with each other, and a wafer transport robot such as an arm robot provided in the wafer transport chamber can unload a wafer in the FOUP into the wafer transport chamber and store a wafer in the FOUP through the load port from the wafer transport chamber. A module consisting of the wafer transport chamber, which provides a space including such a wafer transport robot located therein, along with the load port is referred to as an EFEM, as described above.

The load port is located in front of the wafer transport chamber, and wafers transported by the wafer transport robot through the load port from inside the FOUP into the wafer transport chamber are subjected to various processes or workings in a semiconductor manufacturing apparatus located at the back of the wafer transport chamber, and then stored again in the FOUP through the load port from inside the wafer transport chamber.

There have been known arrangements that have a plurality of such load ports juxtaposed in front of a wafer transport chamber (see Patent Literatures 1 and 2). Onto a loading table of each load port, a FOUP is transferred from above by a FOUP transport device operating along a linear transport line parallel to the juxtaposing direction of the load ports, and a FOUP that contains processed wafers are to be transferred from the loading table to the FOUP transport device.

### CITATION LIST

### Patent Literature

Patent Literature 1: Japanese Patent Laid-Open No. 2010-093227

Patent Literature 2: Japanese Patent Laid-Open No. 2009-016604

### SUMMARY OF INVENTION

### Technical Problem

With the above-described arrangements, the number of load ports juxtaposed in front of a wafer transport chamber can be increased to improve wafer throughput. All juxtaposed load ports, however, require their own installation spaces, resulting in increased installation areas with the increased number of load ports in spite of the improvement in wafer throughput. In addition, the size of the wafer transport chamber, which must be maintained to have a highly clean environment, is also increased, leading to an increase in administration costs.

Accordingly, the inventors have invented a load port, and an EFEM provided with such a load port, with which the number of (accessible) wafers that can be transported to a wafer transport chamber and when the load port is used in an EFEM, throughput can be improved in wafer transportation.

### Solution to Problem

The present invention relates to a load port located in front of a wafer transport chamber and provided with a loading table that can be loaded with a FOUP in which wafers can be stored. Here, one or more load ports of the present invention may be arranged in front of the wafer transport chamber.

The load port according to the present invention includes a plurality of loading tables arranged in a height direction, each of the loading tables being configured to be able to insert/remove wafers stored in a FOUP on each of the loading tables into/from the wafer transport chamber while each of the loading tables is in a wafer insertion/removal position in which the FOUP can be brought into close contact with a front surface of the wafer transport chamber. The load port further includes a transport mechanism for moving the loading tables forward and back in the front/rear direction except at least one on the top between a FOUP passing/receiving position, in which a FOUP is passed/received to/from a FOUP transport device, and the wafer insertion/removal position.

By placing each loading table of a plurality of loading tables arranged in the height direction into the wafer insertion/removal position, the load port thus configured allows the respective FOUP placed on each loading table to insert/remove wafers into/from a wafer transport chamber from the front surface of the wafer transport chamber. This increases the number of wafer access paths (loading and unloading paths) to the wafer transport chamber in the height direction of the load port. Using such load port along with an EFEM, therefore, allows effective use of a space in the height direction without a significant increase in the area required for installing the load port and wafer throughput can significantly be improved.

Further, in the load port of the present invention, a loading table on the top can have the wafer insertion/removal position and the FOUP passing/receiving position collocated in the same position. When a loading table except at least one on the top is moved forward and back in the front/rear direction by the transport mechanism from the wafer insertion/removal position to the FOUP passing/receiving position such that the loading table is moved away from the front surface of the wafer transport chamber to the extent that when viewed in planar view the loading table does not coincide with the one on the top and other tables above the table of interest, the FOUP can be passed/received smoothly between the table of interest and the FOUP transport device. Further, according to the present invention, the moving direction of loading tables by the transport mechanism between the wafer insertion/removal position and the FOUP passing/receiving position is set to the front/back direction. Accordingly, the interference between loading tables adjacent to each other in the height direction can be prevented while each loading table is moved by the transport mechanism, and the movement of the loading table between the wafer insertion/removal position and the FOUP passing/receiving position can be achieved smoothly along a simple and linear moving line.

In particular, according to the present invention, the loading table on the top may be configured to be able to move forward and back in the front/rear direction between the wafer insertion/removal position and the FOUP passing/receiving position. Accordingly, the loading table on the top can also be produced and handled in the same way as other loading tables, providing excellent usefulness.

Further, in order to reduce the number of transport lines of the FOUP passing/receiving position, the FOUP passing/receiving positions of the loading tables except at least one on the top are preferably set to coincide with each other when viewed in planar view. With such a configuration, when a loading table except at least one on the top is positioned at the FOUP passing/receiving position, a FOUP can properly be passed/received between the FOUP transport device operating along a transport line that passes through the FOUP passing/receiving position and the loading table except at least one on the top. Meanwhile, if the FOUP passing/receiving position of the loading tables on the top is also set to coincide with the FOUP passing/receiving positions of other loading tables than the one on the top when viewed in planar view, the FOUP passing/receiving positions of all loading tables coincide with each other when viewed in planar view, and thus a FOUP can properly be passed/received between the FOUP transport device operating along a transport line that passes through the FOUP passing/receiving position and all loading tables.

The EFEM according to the present invention is composed of one or more above-described load ports and a wafer transport chamber with the load ports provided adjacent to a front surface of the load ports. In the EFEM according to the present invention, any number of load ports may be located in front of the wafer transport chamber.

Since the EFEM thus configured is provided with a load port that has advantages as described above, a space in the height direction can effectively be used without an increase in installation area of the load port, and wafer throughput of the entire EFEM can be improved.

### Advantageous Effects of Invention

According to the present invention, there is provided a load port in which a plurality of loading tables are arranged in a height direction and a FOUP placed on each loading table can insert/remove a wafer into/from the wafer transport chamber, so that an increase in the width of the load port, and thus increase in installation area can be prevented and the number of (accessible) wafers that can be transported to the wafer transport chamber can effectively be increased, and that throughput can be improved in wafer transportation when the load port is used in the EFEM. There is also provided an EFEM provided with such a side load port.

### BRIEF DESCRIPTION OF DRAWINGS

FIG. 1 is a plan view schematically illustrating a relative positional relation between an EFEM provided with a load port according to an embodiment of the present invention and a semiconductor manufacturing apparatus.

FIG. 2 is an entire outside drawing of the load port according to the embodiment.

FIG. 3 is a side view of the load port according to the embodiment.

FIG. 4 is a front view of the load port according to the embodiment.

FIG. 5 is a side view of a part (load port unit) of the load port according to the embodiment, with a loading table at the FOUP passing/receiving position.

FIG. 6 is an arrow view taken in Y direction in FIG. 5.

FIG. 7 is an arrow view taken in Z direction in FIG. 5.

FIG. 8 is a side view of a part (load port unit) of the load port according to the embodiment, with a loading table at the wafer insertion/removal position.

FIG. 9 is a graphical representation of the load port in FIG. 8 corresponding to FIG. 6.

FIG. 10 is a graphical representation corresponding to FIG. 3 of a variation of the load port according to the embodiment.

### DESCRIPTION OF EMBODIMENTS

A first embodiment of the present invention will now be described with reference to drawings.

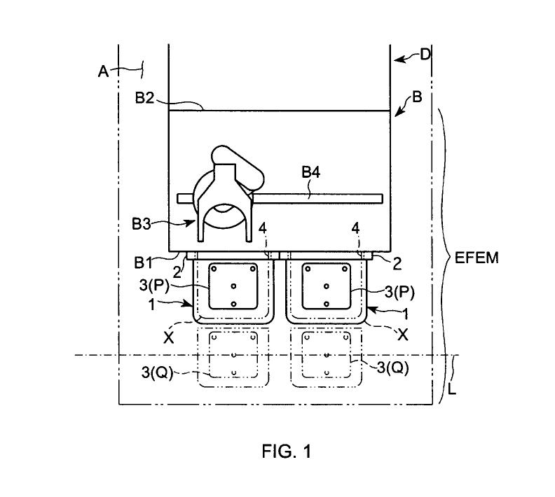

A load port 1 according to an embodiment is used, for example, in a semiconductor manufacturing process and arranged adjacent to a front surface B1 of a wafer transport chamber B in a common clean room A, as illustrated in FIG. 1. The load port 1 constitutes an Equipment Front End Module (EFEM) along with the wafer transport chamber B. A wafer processing apparatus D is provided adjacent to a back surface B2 of the wafer transport chamber B. In the clean room A, the inside of the wafer processing apparatus D, the inside of the wafer transport chamber B, and the inside of a FOUPx are maintained highly clean, while a space in which the load port 1 is located, in other words, the cleanliness of the outside of the wafer processing apparatus D, the outside of the wafer transport chamber B, and the outside of the FOUPx is relatively low. In the embodiment, a plurality (two in the figure) of the load ports 1 are arranged side by side at the front surface B1 of the wafer transport chamber B.

FIG. 1 is a plan view illustrating the load port 1 and its surroundings from above. FIG. 1 schematically illustrates a relative positional relation between the load port 1 and the wafer transport chamber B in the clean room A, and schematically illustrates a relative positional relation between an EFEM composed of the load port 1 along with the wafer transport chamber B and the wafer processing apparatus D.

As illustrated in FIG. 1, provided in the wafer transport chamber B is a wafer transport robot B3 that can transport a wafer in the FOUPx into the wafer processing apparatus D and can transport a wafer appropriately processed in the wafer processing apparatus D into the FOUPx. In the embodiment, the wafer transport robot B3 is configured to be slidable along a slide rail B4 extending in the width direction of the wafer transport chamber B and is configured to be able to access the inside of the FOUPx placed on a loading table 3 of each of the load ports 1 juxtaposed at the front surface B1 of the wafer transport chamber B. The load port 1 of the present invention has multiple stages of loading tables 3 as described below, and the wafer transport robot B3 is configured to be slidable along a slide rail (not shown) extending in the height direction of the wafer transport chamber B and is configured to be able to access the inside of the FOUPx placed on each of the loading tables 3 arranged in the height direction. Note that the number of wafer transport robots B3 that can be provided may be the same as that of loading tables 3 provided in the load port 1 or may be any number constituting other ratios than 1:1 (for example, 2:1) to the number of loading tables 3. The wafer transport robot B3 may be able to transport wafers one by one, may be able to transport a plurality of wafers at a time, or may be able to transport wafers in the FOUPx all at once. Instead of, or in addition to, the wafer transport robot B3, there may be provided in the wafer transport chamber B a cassette transport mechanism that can transport a cassette containing a plurality of wafers between the inside of the FOUPx and the inside of the wafer processing apparatus D.

The FOUPx is configured to be able to contain a plurality of wafers in a multistory manner in the height direction and has a flange portion x1 that can be held by a FOUP transport device such as an overhead hoist transfer (OHP) on the upper surface and handles x2 on the opposite sides. Such a FOUP is well known and further description will be omitted.

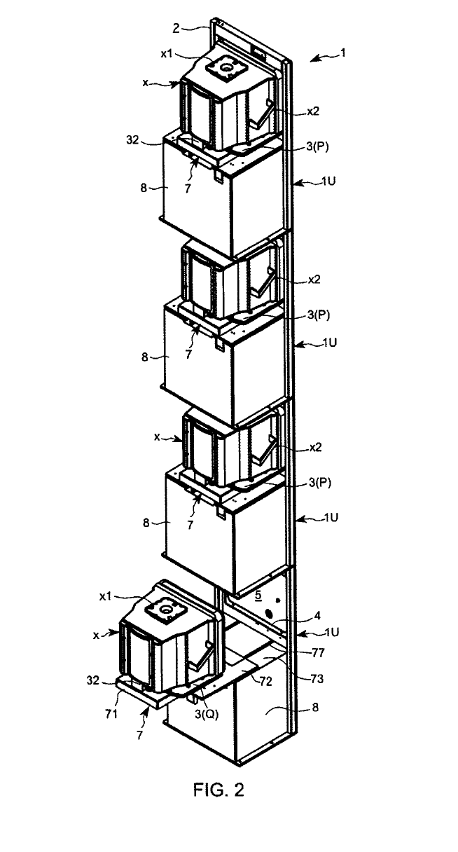

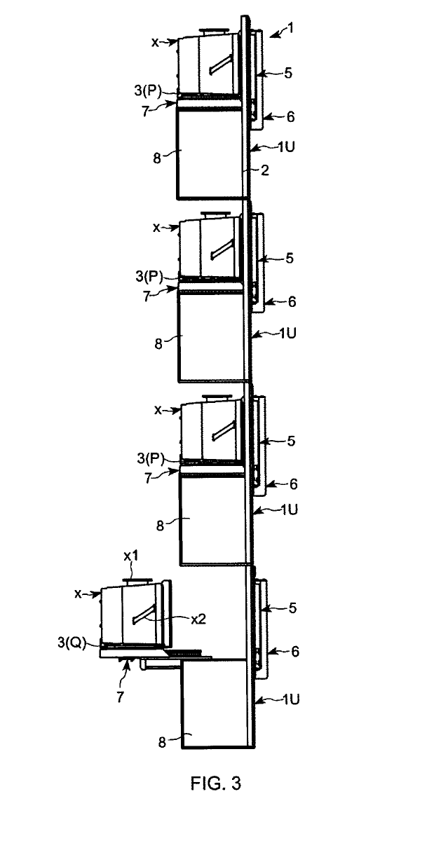

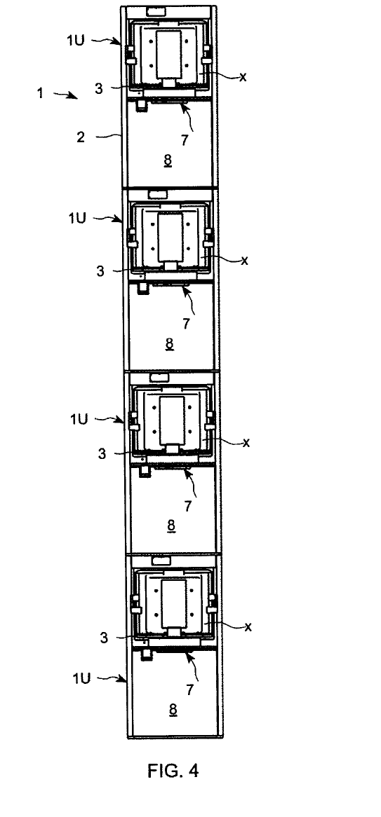

As illustrated in FIGS. 2 to 4, the load port 1 is provided with a frame 2 that has a substantially rectangular plate shape and is placed in a vertical state, multiple stages of loading tables 3 spaced at a predetermined interval in the height direction of the frame 2, an opening 4 that defines a lower edge of the opening at substantially the same level as the upper surface of each of the loading tables 3 in the frame 2 and can be brought into communication with the inside of the wafer transport chamber B, and a door section 5 that opens and closes each opening 4.

Each of the loading tables 3 has protrusions 31 formed thereon protruding upward from a flat top surface (a surface for placing a FOUP) for positioning the FOUPx on the loading table 3 by engaging the protrusions 31 with holes (not shown) formed on the bottom of the FOUPx. The loading tables 3 have at the back end a stopper 32 that forwardly supports the front surface of the FOUPx.

The door section 5 is operable between an opened state in which the door section is brought into close contact with a lid provided in a back surface of the FOUPx while the FOUPx is placed on the loading table 3 and the lid is opened and a closed state in which the internal space of the adjacent wafer transport chamber B is blocked from the internal space of the FOUPx. The specific opening and closing structure is similar to known structures. The directions of switching the state from the closed state to the opened state (opening direction) of all door sections 5 can be the same direction, and in the embodiment, the opening direction of each door section 5 is defined “upward,” for example. The opening direction of the door section 5 associated with the loading table 3 on the top may be different from those of the door sections 5 associated with the second top loading table 3 and those below the second top. The opening direction of the door section 5 associated with the loading table 3 on the bottom may also be different from those of the door sections 5 associated with the second bottom loading table 3 and those above the second bottom. Alternatively, the opening directions of the door sections 5 associated with the loading tables 3 of even numbered stages may be different from those of the door sections 5 associated with the loading tables 3 of odd numbered stages.

The load port 1 according to an embodiment is provided with a mapping apparatus 6 for mapping the number and/or positions of wafers stored in the FOUPx on the loading table 3 placed in a wafer insertion/removal position (P), which will be described later. More than one mapping apparatus 6 may be provided for each loading table 3 individually associated therewith, or a single mapping apparatus 6 may be shared by all loading tables 3. An example mapping apparatus 6 is provided with a mapping rail that is provided on the opposite side to the face of the frame 2 facing the FOUPx (i.e. on the side of the wafer transport chamber B) and that extends in the height direction, a mapping arm that moves along the mapping rail, and a sensor provided on the mapping arm. Each of the loading tables 3 may be provided with a purge port.

The load port 1 thus configured is provided adjacent to the front surface B1 of the wafer transport chamber B and opens and closes the lid of the FOUPx while in close contact with the lid, so that the load port is used to allow the FOUPx to insert/remove wafers into/from the wafer transport chamber B from the front surface B1 of the wafer transport chamber B. In the embodiment, the load port 1 is arranged at the front surface B1 of the wafer transport chamber B with the back surface of the frame 2 being in contact with the front surface B1 of the wafer transport chamber B, as illustrated in FIG. 1. The FOUPx, which is transported by the FOUP transport device operating along a linear transport line (line of flow) extending along the front surface B1 of the wafer transport chamber B, can be transferred from above the load port 1 and placed on the loading table 3 placed in a FOUP passing/receiving position (Q). The FOUPx that contains wafers that have been subjected to a predetermined process (cleaning process in the embodiment) can be passed from the loading table 3 placed in the FOUP passing/receiving position (Q) to the FOUP transport device. Note that in FIG. 1, the loading tables 3 in the wafer insertion/removal position (P), which will be described later, are illustrated by a solid line, and the loading tables 3 in the FOUP passing/receiving position (Q) are illustrated by a long dashed double-short-dashed line.

In the load port 1 that constitutes an EFEM along with the wafer transport chamber B, each of the loading tables 3 is configured to be able to move forward and back in the front/rear direction between the FOUP passing/receiving position (Q), in which the FOUPx can be passed/received to/from the FOUP transport device, and the wafer insertion/removal position (P), in which a wafer stored in the FOUPx can be delivered into the wafer processing apparatus D and a wafer processed in the wafer processing apparatus D can be stored in the FOUPx. The load port 1 of the present invention is provided with a transport mechanism 7 associated with each of the loading tables 3 to move the loading table 3 forward and back in the front/rear direction between the FOUP passing/receiving position (Q) and the wafer insertion/removal position (P).

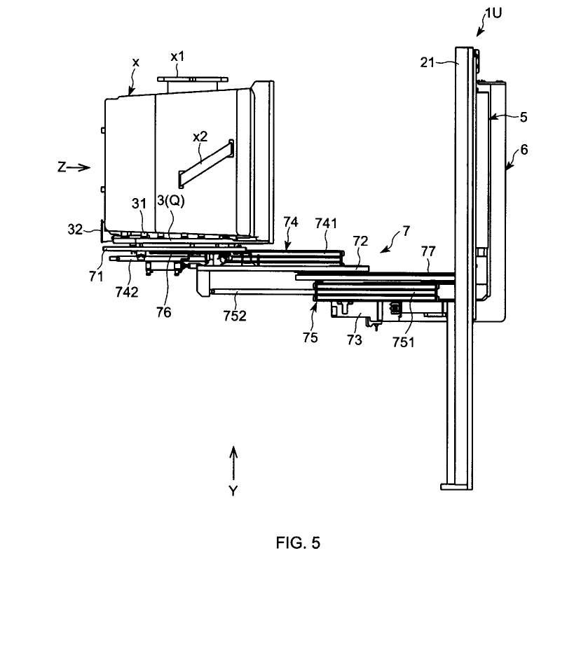

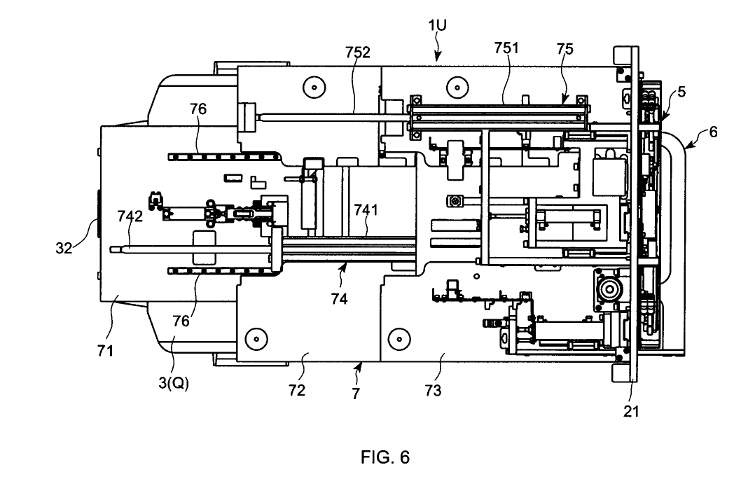

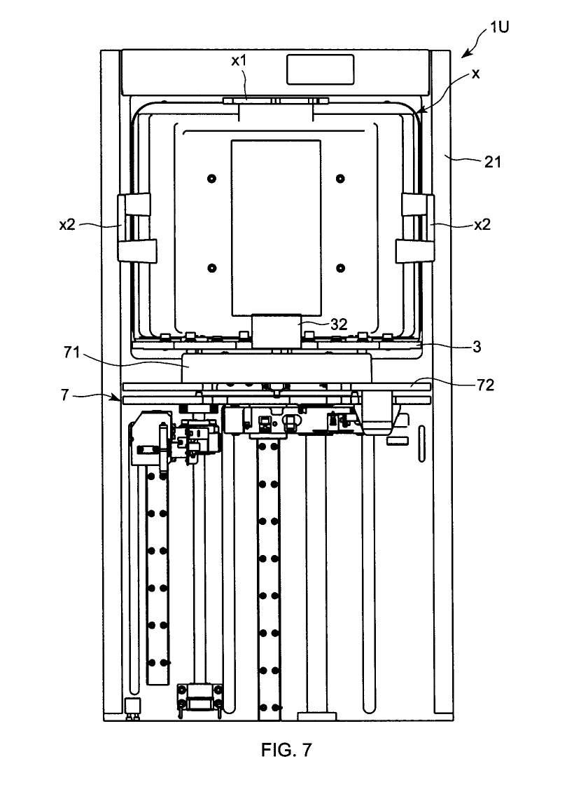

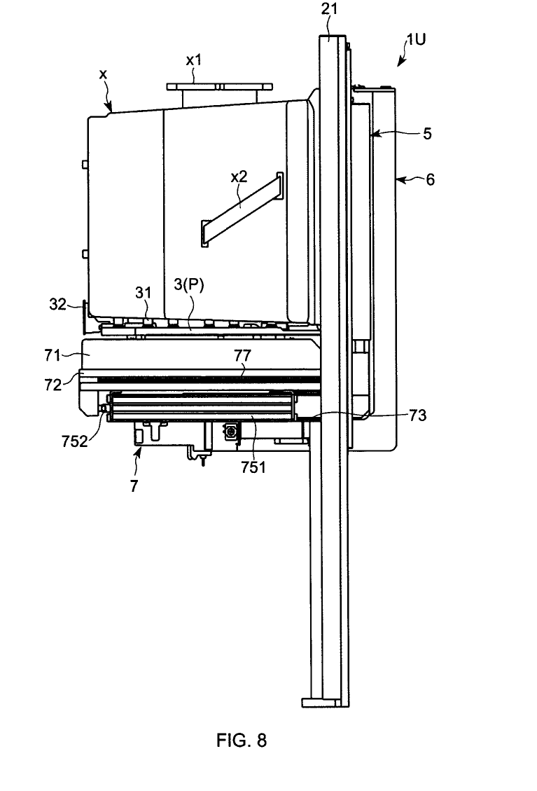

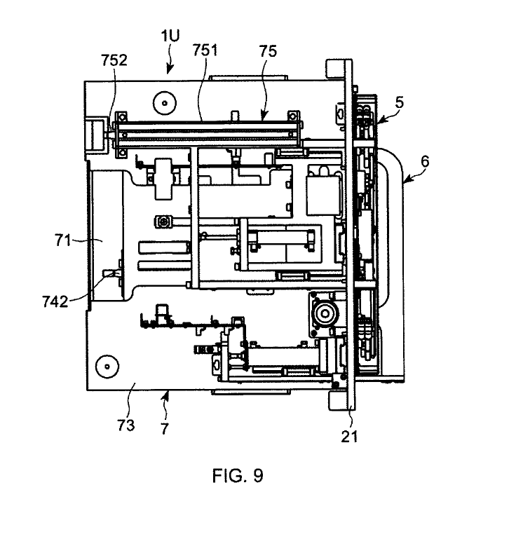

In the embodiment, the load port 1 is composed of more than one load port units 1U, which is composed of a frame element 21 that constitutes the frame 2, the loading table 3, and the transport mechanism 7 as a unit, consecutively arranged in the height direction. FIGS. 5 to 9 illustrate a single load port unit 1U. Each load port unit 1U also incorporates as a unit the door section 5 that opens and closes an opening formed in the frame element 21 and the mapping apparatus 6.

As illustrated in FIG. 5 and other figures, the transport mechanism 7 includes a main slide base 71 that supports the loading table 3 from below, an intermediate slide base 72 that is located under the main slide base 71 and supports the main slide base 71 so that the main slide base 71 is slidable in the front/back direction, and a fixed base 73 that is located under the intermediate slide base 72 and supports the intermediate slide base 72 so that the intermediate slide base 72 is slidable in the front/back direction. The fixed base 73 is fixed to the frame 2. A first actuator 74 is provided between the loading table 3 and the main slide base 71 for moving the loading table 3 forward and back in the front/rear direction relative to the main slide base 71. A second actuator 75 is provided between the intermediate slide base 72 and the fixed base 73 for moving forward and back in the front/rear direction the intermediate slide base 72 relative to the fixed base 73. Each of the first and second actuators 74 and 75 may be formed by a hydraulic cylinder, for example. In the embodiment, the first actuator 74 is formed by a first cylinder main body 741 fixed to the intermediate slide base 72 and a first piston rod 742 that is fixed to the loading table 3 in its distal end and is extendable/retractable relative to the first cylinder main body 741, and the second actuator 75 is formed by a second cylinder main body 751 fixed to the fixed base 73 and a second piston rod 752 that is fixed to the intermediate slide base 72 in its distal end and is extendable/retractable relative to the second cylinder main body 751. The main slide base 71 is provided with a first rail 76 (for example, two rails) on its bottom surface with the longitudinal direction of the first rail 76 being coincident with the moving forward and back in the front/rear direction of the main slide base 71, the first rail 76 being for guiding the withdrawable advance of the main slide base 71. The fixed base 73 is provided with a second rail 77 (for example, two rails) on its top surface with the longitudinal direction of the second rail 77 being coincident with the moving forward and back in the front/rear direction of the intermediate slide base 72, the second rail 77 being for guiding the withdrawable advance of the intermediate slide base 72. Each of the first and second actuators 74 and 75 may have a common driving source or a separate driving source for each actuator. When the loading table 3 of the embodiment is considered as a loading table main body and the main slide base 71 of the embodiment as a loading table supporting slider that is slidable while supporting the loading table main body, the loading of the present invention may be considered as being provided with the loading table main body and the loading table supporting slider. Even in this case, the fact remains that the transport mechanism 7 moves the loading tables forward and back in he front/rear direction between the wafer insertion/removal position (P) and the FOUP passing/receiving position (Q).

The load port 1 of the present invention is configured such that the transport line L of the FOUP transport device intersects the FOUP passing/receiving position (Q) when the loading table 3 is placed in the FOUP passing/receiving position (Q).

The operation of the loading table 3, the transport mechanism 7, the door section 5, and the mapping apparatus 6 is controlled by a controller, which is not shown. In normal use except maintenance or part replacement, all or part of the transport mechanism 7 is covered by a cover 8, although the cover 8 is removed for the sake of explanation in FIGS. 5 to 9.

The use of the load port 1 according to an embodiment and the use of the EFEM will now be described, focusing on the operational procedure of the load port 1 when the load port 1 is used to pass/receive the FOUPx to/from the FOUP transport device, and the operational procedure of the load port 1 when a wafer in the FOUPx is inserted/removed into/from the wafer transport chamber B, and therefore the wafer processing apparatus D, through the load port 1.

First, when the FOUPx transported by the FOUP transport device along the transport line L is to be received, one of a plurality of loading table 3 that is intended to pass/receive the FOUPx to/from the FOUP transport device is placed in the FOUP passing/receiving position (Q) (the loading table 3 on the bottom in FIG. 2 and other figures). The FOUPx transported by the FOUP transport device is then received on the loading table 3 of the load port 1. At this time, the loading table 3 itself does not move up and down. Instead, the FOUP transport device provides up and down movement as necessary so that a FOUP can be passed/received to/from each of the loading tables 3 of different height. Upon receiving the FOUPx on the loading table 3 of the load port 1 as described above, the protrusions 31 provided on the loading table 3 are engaged with holes formed on the bottom of the FOUPx and the stopper 32 provided on the loading table 3 abuts with or against the front surface of the FOUPx. At this point, the FOUPx placed on the loading table 3 assumes a posture such that the lid on the back surface faces the back of the wafer transport chamber B.

The load port 1 of the present invention then slides the loading table 3 from the FOUP passing/receiving position (Q) to the wafer insertion/removal position (P) by means of the transport mechanism 7. Specifically, the actuators 74 and 75 are driven to move the piston rods 742 and 752 in the direction in which the piston rods are retracted into the respective cylinder main bodies 741 and 752, so that the main slide base 71 and the intermediate slide base 72 are slid toward the front surface B1 of the wafer transport chamber B. As a result, the loading table 3 is placed in the wafer insertion/removal position (P) and the lid of the FOUPx on the loading table 3 is brought into close contact with (including contact or adjacent) the door section 5 of the load port 1. At this point, the loading table 3, the main slide base 71, the intermediate slide base 72, and the fixed base 73 are overlapped when viewed in planar view.

The load port 1 of the present invention then performs a process of sequentially delivering wafers in the FOUPx into the wafer transport chamber B through the opening 4 of the load port 1. In the delivery process, the door section 5 of the load port 1 is opened from the closed state while the door section 5 is in close contact with the lid of the FOUPx, a mapping process is performed by the mapping apparatus 6 while the opening 4 is opened, and a wafer with no abnormality detected in the mapping process is delivered to the outside of the FOUPx while the wafer is placed on the arm of the wafer transport robot B3. In the embodiment, the wafer transport robot B3, which is configured to be able to access the inside of the FOUPx placed on each of the load ports 1 located at the front surface B1 of the wafer transport chamber B, is configured to be able to access the inside of the FOUPx on the loading table 3 that is slid from the FOUP passing/receiving position (Q) to the wafer insertion/removal position (P) on the load port 1.

Subsequently, the wafer transport robot B3 in the wafer transport chamber B transports a wafer into the wafer processing apparatus D through the wafer transport chamber B. A wafer appropriately processed in the wafer processing apparatus D is transferred and stored in the FOUPx by the wafer transport robot B3 through the inside of the wafer transport chamber B and the opening 4 of the load port 1. The door section 5 of the load port 1 is then closed from the opened state while the door section 5 is in close contact with the lid of the FOUPx.

Thereafter, the operational procedure of the load port 1 is reversed from the above-described procedure, and the loading table 3 is slid from the wafer insertion/removal position (P) to the FOUP passing/receiving position (Q) by the transport mechanism 7. Specifically, the actuators 74 and 75 are driven to move the piston rods 742 and 752 in the direction in which the piston rods are extended from the respective cylinder main bodies 741 and 752, so that the main slide base 71 and the intermediate slide base 72 are slid away from the front surface B1 of the wafer transport chamber B. As a result, the loading table 3 is placed in the FOUP passing/receiving position (Q) and the FOUPx on the loading table 3 is kept a predetermined distance away from the front surface B1 of the wafer transport chamber B. At this point, the loading table 3, the main slide base 71, the intermediate slide base 72, and the fixed base 73 are stretched in the front/back direction (the moving direction of loading table 3) when viewed in planar view.

Through the above-described steps, the load port 1 of the present invention can place the FOUPx that contains processed wafers in the closed internal space thereof in the FOUP passing/receiving position (Q) and pass the FOUPx on the loading table 3 to the FOUP transport device that transports the FOUPx according to the linear transport line L.

As described above, the load port 1 according to an embodiment is provided with multiple stages of loading tables 3 and places each of the loading tables 3 in the wafer insertion/removal position (P), so that wafers in the FOUPx in the wafer insertion/removal position (P) can be ready for being transported (accessed) to the wafer transport chamber B through the opening 4 associated with and formed on each of the loading tables 3. The provision of an EFEM with the load port 1 thus configured provided adjacent to the front surface B1 of the wafer transport chamber B allows effective use of a space in the height direction without a significant increase in the area required for installing the load port 1 to increase the number of wafer access paths between the load port 1 and the wafer transport chamber B. Wafers in the FOUPx are then ready for being transported to the wafer transport chamber B, and therefore the wafer processing apparatus D, through the load port 1 from the front surface B1 of the wafer transport chamber B, so that a large number of wafers can be processed.

Further, according to the load port 1 of the present invention, the moving direction of the loading tables 3 by the transport mechanism 7 between the wafer insertion/removal position (P) and the FOUP passing/receiving position (Q) is set to be horizontal so that the loading tables 3 are moved toward and away from the front surface B1 of the wafer transport chamber B. Accordingly, the interference between loading tables 3 adjacent to each other in the height direction can be prevented while each loading table 3 is moved by the transport mechanism 7, and the movement of the loading table 3 between the wafer insertion/removal position (P) and the FOUP passing/receiving position (Q) can be achieved smoothly along a simple and linear moving line.

According to the load port 1 of the present invention, all the loading tables 3, including the loading table 3 on the top, are configured to be able to move forward and back in the front/rear direction between the wafer insertion/removal position (P) and the FOUP passing/receiving position (Q), and the FOUP passing/receiving positions (Q) of the respective loading tables 3 are set to coincide with each other when viewed in planar view. Accordingly, the loading table 3 on the top can also be handled in the same use procedure as other loading tables 3, providing excellent operability. Furthermore, the FOUPx can properly be passed/received between the FOUP transport device operating along a transport line that passes through the FOUP passing/receiving position (Q) and all the loading tables 3. As a result, the number of transport lines of the FOUP transport device can be reduced and the FOUP transport device can be simplified.

Since the EFEM according to the embodiment is provided with the load port 1 that has advantages as described above, a space in the height direction can effectively be used without an increase in installation area of the load port 1, and wafer throughput of the entire EFEM can be improved.

Note that the present invention is not limited to the above-described embodiment. For example, the configuration in which a plurality of loading tables are arranged in line in a height direction as illustrated in FIG. 2 and other figures may be modularized and a load port that has a plurality of the modules (load port modules) may be employed. In this case, the load port will have rows of multiple stages of loading tables (loading table row) and the number of rows will depend on the number of modules.

The travel distance of the loading tables moved by the transport mechanism between the FOUP passing/receiving position and the wafer insertion/removal position may vary for each loading table. In this case, if, for example, the travel distance of the loading table on the top is set to be the shortest and the travel distances of the second top loading table 3 and those below the second top are set to be increased toward the bottom, all the loading tables are not overlapped when viewed in planar view when all the loading tables are placed in the FOUP passing/receiving positions, and a FOUP can be passed/received between every loading table and the FOUP transport device. Further in this case, a transport mechanism that slides a loading table on a stage having a dimension corresponding to the travel distance of the loading table in the direction in which the loading table is moved toward and away from the front surface of the wafer transport chamber can be applied.

Alternatively, a configuration in which the wafer insertion/removal position and the FOUP passing/receiving position of the loading table on the top are set to coincide with each other may be adopted. In this case, the FOUP passing/receiving positions of the second top loading table and those below the second top may be set to be farther from the front surface of the wafer transport chamber than the FOUP passing/receiving position of the loading table on the top.

Although a load port including unitized load port units continuously provided in the height direction is illustrated in the above-described embodiment, another load port including multiple stages of loading tables in the common frame may be configured. Note that such a load port unit can advantageously facilitate modification of the number of stages of the loading tables simply by connecting or disconnecting the units.

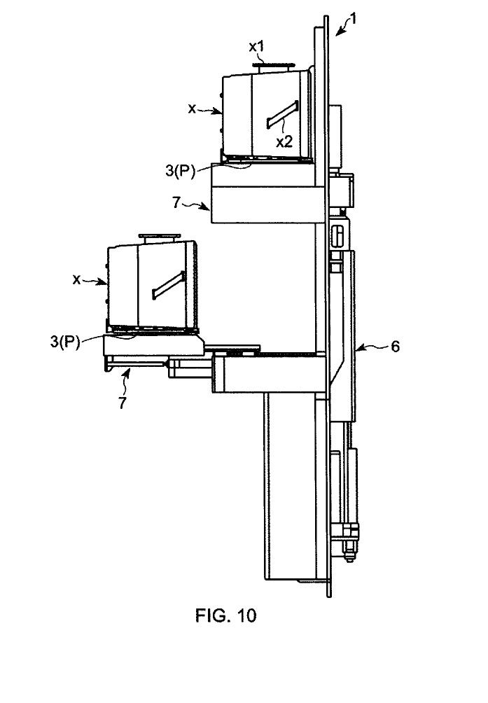

The number of stages of the loading tables is not limited to four stages, and any load port having two stages of loading tables as illustrated in FIG. 10, three stages of loading tables, or five or more stages of loading tables may be used. Note that members and positions in FIG. 10 corresponding to those described above have the same reference characters.

The specific configuration of each section is not limited to the above embodiments, and various modifications can be made without departing from the scope of the present invention, including other forms having one or three or more loading tables in front of the wafer transport chamber.

### INDUSTRIAL APPLICABILITY

The present invention may suitably be applied to the semiconductor manufacturing industries and semiconductor manufacturing tools industries.

1. A load port located in front of a wafer transport chamber, comprising:
a loading table that is loaded with a FOUP in which wafers are stored; and
a transport mechanism,
wherein a plurality of the loading tables are arranged in a height direction, each of the loading tables being configured to be able to insert/remove wafers stored in the FOUP on each of the loading tables into/from the wafer transport chamber while each of the loading tables is in a wafer insertion/removal position in which the FOUP is brought into close contact with a front surface of the wafer transport chamber, and
the transport mechanism moves the loading tables forward and back in the front/rear direction except at least one on the top between a FOUP passing/receiving position, in which a FOUP is passed/received to/from a FOUP transport device, and the wafer insertion/removal position.

2. The load port according to claim 1, wherein
the loading table on the top is configured to be able to move forward and back in the front/rear direction between the wafer insertion/removal position and the FOUP passing/receiving position.

3. The load port according to claim 1, wherein
the FOUP passing/receiving positions of the loading tables except at least one on the top are set to coincide with each other when viewed in planar view.

4. An EFEM, comprising:
one or more load ports according to claim 1; and
a wafer transport chamber with the load ports provided adjacent to a front surface of the load ports.

5. The load port according to claim 2, wherein
the FOUP passing/receiving positions of the loading tables except at least one on the top are set to coincide with each other when viewed in planar view.

6. An EFEM, comprising:
one or more load ports according to claim 2; and
a wafer transport chamber with the load ports provided adjacent to a front surface of the load ports.

7. An EFEM, comprising:
one or more load ports according to claim 3; and
a wafer transport chamber with the load ports provided adjacent to a front surface of the load ports.
